(19) United States
(12) Patent Application Publication
(10) Pub. No.: US 2007/0163643 A1
(43) Pub. Date: Jul. 19, 2007

(54) High-throughput printing of chalcogen layer and the use of an inter-metallic material

(75) Inventors: Jeroen K.J. Van Duren, Menlo Park, CA (US); Matthew R. Robinson, East Palo Alto, CA (US); Brian M. Sager, Palo Alto, CA (US)

Correspondence Address: NANOSOLAR, INC., 2440 EMBARCADERO WAY, PALO ALTO, CA, 94303, US

(73) Assignee: Nanosolar, Inc., Palo Alto, CA (US)

(21) Appl. No.: 11/395,438

(22) Filed: Mar. 30, 2006

Related U.S. Application Data
(63) Continuation-in-part of application No. 11/243,522, filed on Oct. 3, 2005.
Application No. 11/243,522 is a continuation-in-part of application No. 10/782,017, filed on Feb. 19, 2004.
(63) Continuation-in-part of application No. 10/943,657, filed on Sep. 18, 2004.
(63) Continuation-in-part of application No. 11/081,163, filed on Mar. 16, 2005.
(63) Continuation-in-part of application No. 10/943,685, filed on Sep. 18, 2004.

(51) Int. Cl. B05D 3/00

(52) U.S. Cl. 136/262; 136/264; 136/265; 427/190

(57) ABSTRACT

Methods and devices for high-throughput printing of a precursor material for forming a film of a group IB-IIIA-chalcogenide compound are disclosed. In one embodiment, the method comprises forming a precursor layer on a substrate, wherein the precursor layer comprises one or more discrete layers. The layers may include at least a first layer containing one or more group IB elements and two or more different group IIIA elements and at least a second layer containing elemental chalcogen particles. The precursor layer may be heated to a temperature sufficient to melt the chalcogen particles and to react the chalcogen particles with the one or more group IB elements and group IIIA elements in the precursor layer to form a film of a group IB-IIIA-chalcogenide compound. At least one set of the particles in the precursor layer are inter-metallic particles containing at least one group IB-IIIA inter-metallic alloy phase. The method may also include making a film of group IB-IIIA-chalcogenide compound that includes mixing the nanoparticles and/or nanoglobules and/or nanodroplets to form an ink, depositing the ink on a substrate, heating to melt the extra chalcogen and to react the chalcogen with the group IB and group IIIA elements and/or chalcogenides to form a dense film.

### CROSS-REFERENCE TO RELATED APPLICATION

This application is a continuation-in-part of commonly-assigned, co-pending application Ser. No. 11/243,522 entitled “HIGH-THROUGHPUT PRINTING OF CHALCOGEN LAYER” filed Feb. 23, 2006, which is a continuation-in-part of commonly-assigned, co-pending application Ser. No. 11/290,633 entitled “CHALCOGENIDE SOLAR CELLS” filed Nov. 29, 2005 and Ser. No. 10/782,017, entitled “SOLUTION-BASED FABRICATION OF PHOTOVOLTAIC CELL” filed Feb. 19, 2004 and published as U.S. patent application publication 20050183767. This application is also a continuation-in-part of commonly-assigned, co-pending U.S. patent application Ser. No. 10/943,657, entitled “COATED NANOPARTICLES AND QUANTUM DOTS FOR SOLUTION-BASED FABRICATION OF PHOTOVOLTAIC CELLS” filed Sep. 18, 2004. This application is a also continuation-in-part of commonly-assigned, co-pending U.S. patent application Ser. No. 11/081,163, entitled “METALLIC DISPERSION”, filed Mar. 16, 2005. This application is a also continuation-in-part of commonly-assigned, co-pending U.S. patent application Ser. No. 10/943,685, entitled “FORMATION OF CIGS ABSORBER LAYERS ON FOIL SUBSTRATES”, filed Sep. 18, 2004. All of the above applications are fully incorporated herein by reference for all purposes.

### FIELD OF THE INVENTION

This invention relates to solar cells and more specifically to fabrication of solar cells that use active layers based on IB-IIIA-VIA compounds.

### BACKGROUND OF THE INVENTION

Solar cells and solar modules convert sunlight into electricity. These electronic devices have been traditionally fabricated using silicon (Si) as a light-absorbing, semiconducting material in a relatively expensive production process. To make solar cells more economically viable, solar cell device architectures have been developed that can inexpensively make use of thin-film, light-absorbing semiconductor materials such as, but not limited to, copper-indium-gallium-sulfo-di-selenide, Cu(In, Ga)(S, Se)₂, also termed CI(G)S(S). This class of solar cells typically has a p-type absorber layer sandwiched between a back electrode layer and an n-type junction partner layer. The back electrode layer is often Mo, while the junction partner is often CdS. A transparent conductive oxide (TCO) such as, but not limited to, zinc oxide (ZnOₓ) is formed on the junction partner layer and is typically used as a transparent electrode. CIS-based solar cells have been demonstrated to have power conversion efficiencies exceeding 19%.

A central challenge in cost-effectively constructing a large-area CIGS-based solar cell or module is that the elements of the CIGS layer must be within a narrow stoichiometric ratio on nano-, meso-, and macroscopic length scale in all three dimensions in order for the resulting cell or module to be highly efficient. Achieving precise stoichiometric composition over relatively large substrate areas is, however, difficult using traditional vacuum-based deposition processes. For example, it is difficult to deposit compounds and/or alloys containing more than one element by sputtering or evaporation. Both techniques rely on deposition approaches that are limited to line-of-sight and limited-area sources, tending to result in poor surface coverage. Line-of-sight trajectories and limited-area sources can result in non-uniform three-dimensional distribution of the elements in all three dimensions and/or poor film-thickness uniformity over large areas. These non-uniformities can occur over the nano-, meso-, and/or macroscopic scales. Such non-uniformity also alters the local stoichiometric ratios of the absorber layer, decreasing the potential power conversion efficiency of the complete cell or module.

Alternatives to traditional vacuum-based deposition techniques have been developed. In particular, production of solar cells on flexible substrates using non-vacuum, semiconductor printing technologies provides a highly cost-efficient alternative to conventional vacuum-deposited solar cells. For example, T. Arita and coworkers [20th IEEE PV Specialists Conference, 1988, page 1650] described a non-vacuum, screen printing technique that involved mixing and milling pure Cu, In and Se powders in the compositional ratio of 1:1:2 and forming a screen printable paste, screen printing the paste on a substrate, and sintering this film to form the compound layer. They reported that although they had started with elemental Cu, In and Se powders, after the milling step the paste contained the CuInSe₂ phase. However, solar cells fabricated from the sintered layers had very low efficiencies because the structural and electronic quality of these absorbers was poor.

Screen-printed CuInSe₂ deposited in a thin-film was also reported by A. Vervaet et al. [9th European Communities PV Solar Energy Conference, 1989, page 480], where a micron-sized CuInSe₂ powder was used along with micron-sized Se powder to prepare a screen printable paste. Layers formed by non-vacuum, screen printing were sintered at high temperature. A difficulty in this approach was finding an appropriate fluxing agent for dense CuInSe₂ film formation. Even though solar cells made in this manner had poor conversion efficiencies, the use of printing and other non-vacuum techniques to create solar cells remains promising.

Others have tried using chalcogenide powders as precursor material, e.g. micron-sized CIS powders deposited via screen-printing, amorphous quaternary selenide nanopowder or a mixture of amorphous binary selenide nanopowders deposited via spraying on a hot substrate, and other examples [(1) Vervaet, A. et al., E. C. Photovoltaic Sol. Energy Conf., Proc. Int. Conf., 10th (1991), 900-3.; (2) Journal of Electronic Materials, Vol. 27, No. 5, 1998, p. 433; Ginley et al.; (3) WO 99,378,32; Ginley et al.; (4) U.S. Pat. No. 6,126,740]. So far, no promising results have been obtained when using chalcogenide powders for fast processing to form CIGS thin-films suitable for solar cells.

Due to high temperatures and/or long processing times required for sintering, formation of a IB-IIIA-chalcogenide compound film suitable for thin-film solar cells is challenging when starting from IB-IIIA-chalcogenide powders where each individual particle contains appreciable amounts of all IB, IIIA, and VIA elements involved, typically close to the stoichiometry of the final IB-IIIA-chalcogenide compound film. Poor uniformity was evident by a wide range of heterogeneous layer features, including but not limited to porous layer structure, voids, gaps, cracking, and regions of relatively low-density. This non-uniformity is exacerbated by the complicated sequence of phase transformations undergone during the formation of CIGS crystals from precursor materials. In particular, multiple phases forming in discrete areas of the nascent absorber film will also lead to increased non-uniformity and ultimately poor device performance.

The requirement for fast processing then leads to the use of high temperatures, which would damage temperature-sensitive foils used in roll-to-roll processing. Indeed, temperature-sensitive substrates limit the maximum temperature that can be used for processing a precursor layer into CIS or CIGS to a level that is typically well below the melting point of the ternary or quaternary selenide (>900° C.). A fast and high-temperature process, therefore, is less preferred. Both time and temperature restrictions, therefore, have not yet resulted in promising results on suitable substrates using ternary or quaternary selenides as starting materials.

As an alternative, starting materials may be based on a mixture of binary selenides, which at a temperature above 500° C. would result in the formation of a liquid phase that would enlarge the contact area between the initially solid powders and, thereby, accelerate the sintering process as compared to an all-solid process. Unfortunately, below 500° C. no liquid phase is created.

Thus, there is a need in the art for a one-step, rapid yet low-temperature technique for fabricating high-quality and uniform CIGS films for solar modules and suitable precursor materials for fabricating such films.

### SUMMARY OF THE INVENTION

The disadvantages associated with the prior art are overcome by embodiments of the present invention directed to the introduction of IB and IIIA elements in the form of chalcogenide nanopowders and combining these chalcogenide nanopowders with an additional source of chalcogen such as selenium or sulfur, tellurium or a mixture of two or more of these, to form a group IB-IIIA-chalcogenide compound. According to one embodiment a compound film may be formed from a mixture of: 1) binary or multi-nary selenides, sulfides, or tellurides and 2) elemental selenium, sulfur or tellurium. According to another embodiment, the compound film may be formed using core-shell nanoparticles having core nanoparticles containing group IB and/or group IIIA elements coated with a non-oxygen chalcogen material. In yet another embodiment of the present invention, the chalcogen may also be deposited with the precursor material and not in a separate, discrete layer.

In one embodiment, the method comprises forming a precursor layer on a substrate, wherein the precursor layer comprises one or more discrete layers. The layers may include at least a first layer containing one or more group IB elements and two or more different group IIIA elements and at least a second layer containing elemental chalcogen particles. The precursor layer may be heated to a temperature sufficient to melt the chalcogen particles and to react the chalcogen particles with the one or more group IB elements and group IIIA elements in the precursor layer to form a film of a group IB-IIIA-chalcogenide compound. The method may also include making a film of group IB-IIIA-chalcogenide compound that includes mixing the nanoparticles and/or nanoglobules and/or nanodroplets to form an ink, depositing the ink on a substrate, heating to melt the extra chalcogen and to react the chalcogen with the group IB and group IIIA elements and/or chalcogenides to form a dense film. In some embodiments, densification of the precursor layer is not used since the absorber layer may be formed without first sintering the precursor layer to a temperature where densification occurs. At least one set of the particles in the precursor layer are inter-metallic particles containing at least one group IB-IIIA inter-metallic alloy phase. Alternatively, at least one set of the particles in the precursor layer are formed from a feedstock of inter-metallic particles containing at least one group IB-IIIA inter-metallic alloy phase.

Optionally, the first layer may be formed over the second layer. In another embodiment, the second layer may be formed over the first layer. The first layer may also contain elemental chalcogen particles. The first layer may have group IB elements in the form of a group IB-chalcogenide. The first layer may have group IIIA elements in the form of a group IIIA-chalcogenide. There may be a third layer containing elemental chalcogen particles. The two or more different group IIIA elements may include indium and gallium. The group IB element may be copper. The chalcogen particles may be particles of selenium, sulfur, and/or tellurium. The precursor layer may be substantially oxygen-free. Forming the precursor layer may include forming a dispersion including nanoparticles containing one or more group IB elements and nanoparticles containing two or more group IIIA elements, spreading a film of the dispersion onto the substrate. Forming the precursor layer may include sintering the film to form the precursor layer. Sintering the precursor layer may take place before the step of disposing the layer containing elemental chalcogen particles over the precursor layer. The substrate may be a flexible substrate and wherein forming the precursor layer and/or disposing the layer containing elemental chalcogen particles over the precursor layer, and/or heating the precursor layer and chalcogen particles includes the use of roll-to-roll manufacturing on the flexible substrate. The substrate may be an aluminum foil substrate. The group IB-IIIA-chalcogenide compound may be of the form CuzIn(1−x)GaxS2(1−y)Se2y, where 0.5≦z≦1.5, 0≦x≦1.0 and 0≦y≦1.0.

In another embodiment of the present invention, heating of precursor layer and chalcogen particles may include heating the substrate and precursor layer from an ambient temperature to a plateau temperature range of between about 200° C. and about 600° C., maintaining a temperature of the substrate and precursor layer in the plateau range for a period of time ranging between about a fraction of a second to about 60 minutes, and subsequently reducing the temperature of the substrate and precursor layer.

In a still further embodiment of the present invention, a method is provided for forming a film of a group IB-IIIA-chalcogenide compound. The method includes forming a precursor layer on a substrate, wherein the precursor layer contains one or more group IB elements and one or more group IIIA elements. The method may include sintering the precursor layer. After sintering the precursor layer, the method may include forming a layer containing elemental chalcogen particles over the precursor layer. The method may also include heating the precursor layer and chalcogen particles to a temperature sufficient to melt the chalcogen particles and to react the chalcogen particles with the group IB element and group IIIA elements in the precursor layer to form a film of a group IB-IIIA-chalcogenide compound. The one or more group IIIA elements may include indium and gallium. The chalcogen particles may be particles of selenium, sulfur or tellurium. The precursor layer may be substantially oxygen-free. The method may include forming the precursor layer which includes forming a dispersion containing nanoparticles containing one or more group IB elements and nanoparticles containing two or more group IIIA elements, spreading a film of the dispersion onto a substrate. The method may include forming the precursor layer and/or sintering the precursor layer and/or disposing the layer containing elemental chalcogen particles over the precursor layer and/or heating the precursor layer and chalcogen particles to a temperature sufficient to melt the chalcogen particles includes the use of roll-to-roll manufacturing on the flexible substrate. The group IB-IIIA-chalcogenide compound may be of the form CuzIn(1−x)GaxS2(1−y)Se2y, where 0.5≦z≦1.5, 0≦x≦1.0and 0≦y≦1.0.

In yet another embodiment of the present invention, sintering the precursor layer may include heating the substrate and precursor layer from an ambient temperature to a plateau temperature range of between about 200° C. and about 600° C., maintaining a temperature of the substrate and precursor layer in the plateau range for a period of time ranging between about a fraction of a second to about 60 minutes, and subsequently reducing the temperature of the substrate and precursor layer. Heating the precursor layer and chalcogen particles may include heating the substrate, precursor layer, and chalcogen particles from an ambient temperature to a plateau temperature range of between about 200° C. and about 600° C., maintaining a temperature of the substrate and precursor layer in the plateau range for a period of time ranging between about a fraction of a second to about 60 minutes, and subsequently reducing the temperature of the substrate and precursor layer. It should also be understood that the substrate may be an aluminum foil substrate.

In a still further embodiment of the present invention, a method is provided that is comprised of forming a precursor layer containing particles having one or more group IB elements and two or more different group IIIA elements and forming a layer containing surplus chalcogen particles providing a source of excess chalcogen, wherein the precursor layer and the surplus chalcogen layer are adjacent to one another. The precursor layer and the surplus chalcogen layer are heated to a temperature sufficient to melt the particles providing the source of excess chalcogen and to react the particles with the one or more group IB elements and group IIIA elements in the precursor layer to form a film of a group IB-IIIA-chalcogenide compound on a substrate. The surplus chalcogen layer may be formed over the precursor layer. The surplus chalcogen layer may be formed under the precursor layer. The particles providing the source of excess chalcogen may be comprised of elemental chalcogen particles. The particles providing the source of excess chalcogen may be comprised of chalcogenide particles. The particles providing the source of excess chalcogen may be comprised of chalcogen-rich chalcogenide particles. The precursor layer may also contain elemental chalcogen particles. The precursor layer may have group IB elements in the form of a group IB-chalcogenide. The precursor layer may have group IIIA elements in the form of a group IIIA-chalcogenide. A third layer may be provided that contains elemental chalcogen particles. The film may be formed from the precursor layer of the particles and a layer of a sodium-containing material in contact with the precursor layer.

Optionally, the film may be formed from a precursor layer of the particles and a layer in contact with the precursor layer and containing at least one of the following materials: a group IB element, a group IIIA element, a group VIA element, a group IA element, a binary and/or multinary alloy of any of the preceding elements, a solid solution of any of the preceding elements, copper, indium, gallium, selenium, copper indium, copper gallium, indium gallium, sodium, a sodium compound, sodium fluoride, sodium indium sulfide, copper selenide, copper sulfide, indium selenide, indium sulfide, gallium selenide, gallium sulfide, copper indium selenide, copper indium sulfide, copper gallium selenide, copper gallium sulfide, indium gallium selenide, indium gallium sulfide, copper indium gallium selenide, and/or copper indium gallium sulfide. In one embodiment, the particles contain sodium at about 1 at.% or less. The particles may contain at least one of the following materials: Cu—Na, In—Na, Ga—Na, Cu—In—Na, Cu—Ga—Na, In—Ga—Na, Na—Se, Cu—Se—Na, In—Se—Na, Ga—Se—Na, Cu—In—Se—Na, Cu—Ga—Se—Na, In—Ga—Se—Na, Cu—In—Ga—Se—Na, Na—S, Cu—S—Na, In—S—Na, Ga—S—Na, Cu—In—S—Na, Cu—Ga—S—Na, In—Ga—S—Na, or Cu—In—Ga—S—Na. The film may be formed from a precursor layer of the particles and an ink containing a sodium compound with an organic counter-ion or a sodium compound with an inorganic counter-ion. Optionally, the film may be formed from a precursor layer of the particles and a layer of a sodium containing material in contact with the precursor layer and/or particles containing at least one of the following materials: Cu—Na, In—Na, Ga—Na, Cu—In—Na, Cu—Ga—Na, In—Ga—Na, Na—Se, Cu—Se—Na, In—Se—Na, Ga—Se—Na, Cu—In—Se—Na, Cu—Ga—Se—Na, In—Ga—Se—Na, Cu—In—Ga—Se—Na, Na—S, Cu—S—Na, In—S—Na, Ga—S—Na, Cu—In—S—Na, Cu—Ga—S—Na, In—Ga—S—Na, or Cu—In—Ga—S—Na; and/or an ink containing the particles and a sodium compound with an organic counter-ion or a sodium compound with an inorganic counter-ion. The method may also include adding a sodium containing material to the film after the heating step.

In another embodiment, a liquid ink may be made using one or more liquid metals. For example, an ink may be made starting with a liquid and/or molten mixture of Gallium and/or Indium. Copper nanoparticles may then be added to the mixture, which may then be used as the ink/paste. Copper nanoparticles are available commercially. Alternatively, the temperature of the Cu—Ga—In mixture may be adjusted (e.g. cooled) until a solid forms. The solid may be ground at that temperature until small nanoparticles (e.g., less than 5 nm) are present. Selenium may be added to the ink and/or a film formed from the ink by exposure to selenium vapor, e.g., before, during, or after annealing.

In another embodiment, a liquid ink may be made using one or more liquid metals. For example, an ink may be made starting with a liquid and/or molten mixture of Gallium and/or Indium. Copper nanoparticles may then be added to the mixture, which may then be used as the ink/paste. Copper nanoparticles are available commercially. Alternatively, the temperature of the Cu—Ga—In mixture may be adjusted (e.g. cooled) until a solid forms. The solid may be ground at that temperature until small nanoparticles (e.g., less than 5 nm) are present. Selenium may be added to the ink and/or a film formed from the ink by exposure to selenium vapor, e.g., before, during, or after annealing.

In yet another embodiment of the present invention, a process is described comprising of formulating a dispersion of solid and/or liquid particles comprising group IB and/or IIIA elements, and, optionally, at least one group VIA element. The process includes depositing the dispersion onto a substrate to form a layer on the substrate and reacting the layer in a suitable atmosphere to form a film. In this process, at least one set of the particles are inter-metallic particles containing at least one group IB-IIIA inter-metallic phase.

In yet another embodiment of the present invention, a composition is provided comprised of a plurality of particles comprising group IB and/or IIIA elements, and, optionally, at least one group VIA element. At least one set of the particles contains at least one group IB-IIIA inter-metallic alloy phase.

In a still further embodiment of the present invention, the method may include formulating a dispersion of particles comprising group IB and/or IIIA elements, and, optionally, at least one group VIA element. The method may include depositing the dispersion onto a substrate to form a layer on the substrate and reacting the layer in a suitable atmosphere to form a film. At least one set of the particles contain a group IB-poor, group IB-IIIA alloy phase. In some embodiments, group IB-poor particles contribute less than about 50 molar percent of group IB elements found in all of the particles. The group IB-poor, group IB-IIIA alloy phase particles may be a sole source of one of the group IIIA elements. The group IB-poor, group IB-IIIA alloy phase particles may contain an inter-metallic phase and may be a sole source of one of the group IIIA elements. The group IB-poor, group IB-IIIA alloy phase particles may contain an inter-metallic phase and are a sole source of one of the group IIIA elements. The group IB-poor, group IB-IIIA alloy phase particles may be Cu₁In₂ particles and are a sole source of indium in the material.

It should be understood that for any of the foregoing the film and/or final compound may include a group IB-IIIA-VIA compound. The reacting step may comprise of heating the layer in the suitable atmosphere. The depositing step may include coating the substrate with the dispersion. At least one set of the particles in the dispersion may be in the form of nanoglobules. At least one set of the particles in the dispersion may be in the form of nanoglobules and contain at least one group IIIA element. At least one set of the particles in the dispersion may be in the form of nanoglobules comprising of a group IIIA element in elemental form. In some embodiments of the present invention, the inter-metallic phase is not a terminal solid solution phase. In some embodiments of the present invention, the inter-metallic phase is not a solid solution phase. The inter-metallic particles may contribute less than about 50 molar percent of group IB elements found in all of the particles. The inter-metallic particles may contribute less than about 50 molar percent of group IIIA elements found in all of the particles. The inter-metallic particles may contribute less than about 50 molar percent of the group IB elements and less than about 50 molar percent of the group IIIA elements in the dispersion deposited on the substrate. The inter-metallic particles may contribute less than about 50 molar percent of the group IB elements and more than about 50 molar percent of the group IIIA elements in the dispersion deposited on the substrate. The inter-metallic particles may contribute more than about 50 molar percent of the group IB elements and less than about 50 molar percent of the group IIIA elements in the dispersion deposited on the substrate. The molar percent for any of the foregoing may be based on a total molar mass of the elements in all particles present in the dispersion. In some embodiments, at least some of the particles have a platelet shape. In some embodiments, a majority of the particles have a platelet shape. In other embodiments, substantially all of the particles have a platelet shape.

For any of the foregoing embodiments, an inter-metallic material for use with the present invention is a binary material. The inter-metallic material may be a ternary material. The inter-metallic material may comprise of Cu₁In₂. The inter-metallic material may be comprised of a composition in a δ phase of Cu₁In₂. The inter-metallic material may be comprised of a composition in between a δ phase of Cu₁In₂ and a phase defined by Cu16In9. The inter-metallic material may be comprised of Cu₁Ga₂. The inter-metallic material may be comprised of an intermediate solid-solution of Cu₁Ga₂. The inter-metallic material may be comprised of Cu₆₈Ga₃₈. The inter-metallic material may be comprised of Cu₇₀Ga₃₀. The inter-metallic material may be comprised of Cu₇₅Ga₂₅. The inter-metallic material may be comprised of a composition of Cu—Ga of a phase in between the terminal solid-solution and an intermediate solid-solution next to it. The inter-metallic may be comprised of a composition of Cu—Ga in a γ1 phase (about 31.8 to about 39.8 wt % Ga). The inter-metallic may be comprised of a composition of Cu—Ga in a γ2 phase (about 36.0 to about 39.9 wt % Ga). The inter-metallic may be comprised of a composition of Cu—Ga in a γ3 phase (about 39.7 to about −44.9 wt % Ga). The inter-metallic may be comprised of a composition of Cu—Ga in a phase between γ2 and γ3. The inter-metallic may be comprised of a composition of Cu—Ga in a phase between the terminal solid solution and γ1. The inter-metallic may be comprised of a composition of Cu—Ga in a θ phase (about 66.7 to about 68.7 wt % Ga). The inter-metallic material may be comprised of Cu-rich Cu—Ga. Gallium may be incorporated as a group IIIA element in the form of a suspension of nanoglobules. Nanoglobules of gallium may be formed by creating an emulsion of liquid gallium in a solution. Gallium nanoglobules may be created by being quenched below room temperature.

A process according to the any of the foregoing embodiments of the present invention may include maintaining or enhancing a dispersion of liquid gallium in solution by stirring, mechanical means, electromagnetic means, ultrasonic means, and/or the addition of dispersants and/or emulsifiers. The process may include adding a mixture of one or more elemental particles selected from: aluminum, tellurium, or sulfur. The suitable atmosphere may contain selenium, sulfur, tellurium, H₂, CO, H₂Se, H₂S, Ar, N₂ or combinations or mixture thereof. The suitable atmosphere may contain at least one of the following: H₂, CO, Ar, and N₂. One or more classes of the particles may be doped with one or more inorganic materials. Optionally, one or more classes of the particles are doped with one or more inorganic materials chosen from the group of aluminum (Al), sulfur (S), sodium (Na), potassium (K), or lithium (Li).

Optionally, embodiments of the present invention may include having a copper source that does not immediately alloy with In, and/or Ga. One option would be to use (slightly) oxidized copper. The other option would be to use CuxSey. Note that for the (slightly) oxidized copper approach, a reducing step may be desired. Basically, if elemental copper is used in liquid In and/or Ga, speed of the process between ink preparation and coating should be sufficient so that the particles have not grown to a size that will result in thickness non-uniform coatings.

It should be understood that the temperature range may that of the substrate only since that is typically the only one that should not be heated above its melting point. This holds for the lowest melting material in the substrate, being Al and other suitable substrates.

A further understanding of the nature and advantages of the invention will become apparent by reference to the remaining portions of the specification and drawings.

### BRIEF DESCRIPTION OF THE DRAWINGS

FIGS. 1A-1E are a sequence of schematic cross-sectional diagrams illustrating fabrication of a photovoltaic active layer according to an embodiment of the present invention.

FIG. 1F shows yet another embodiment of the present invention.

FIGS. 2A-2F are a sequence of schematic cross-sectional diagrams illustrating fabrication of a photovoltaic active layer according to an alternative embodiment of the present invention.

FIG. 2G is a schematic diagram of a roll-to-roll processing apparatus that may be used with embodiments of the present invention.

FIG. 3 is a cross-sectional schematic diagram of a photovoltaic device having an active layer fabricated according to an embodiment of the present invention.

FIG. 4A shows one embodiment of a system for use with rigid substrates according to one embodiment of the present invention.

FIG. 4B shows one embodiment of a system for use with rigid substrates according to one embodiment of the present invention.

FIGS. 5-7 show the use of inter-metallic material to form a film according to embodiments of the present invention.

FIG. 8 is a cross-sectional view showing the use of multiple layers to form a film according to embodiments of the present invention.

FIG. 9 shows feedstock material being processed according to embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for a barrier film, this means that the barrier film feature may or may not be present, and, thus, the description includes both structures wherein a device possesses the barrier film feature and structures wherein the barrier film feature is not present.

According to one embodiment of the present invention, an active layer for a photovoltaic device may be fabricated by first forming a group IB-IIIA compound layer, disposing a group VIA particulate on the compound layer and then heating the compound layer and group VIA particulate to form a group IB-IIIA-VIA compound. Preferably, the group IB-IIIA compound layer is a compound of copper (Cu), indium (In) and Gallium (Ga) of the form Cu_{z}InₓGa₁₋ₓ, where 0≦x≦1 and 0.5≦z≦1.5. The group IB-IIIA-VIA compound preferably is a compound of Cu, In, Ga and selenium (Se) or sulfur S of the form CuIn₍₁₋ₓ₎GaₓS_{2(1-y)}Se_{2y}, where 0≦x≦1 and 0≦y≦1. It should also be understood that the resulting group IB-IIIA-VIA compound may be a compound of Cu, In, Ga and selenium (Se) or sulfur S of the form Cu_{z}In₍₁₋ₓ₎GaₓS_{2(1-y)}Se_{2y}, where 0.5≦z≦1.5, 0≦x≦1.0 and 0≦y≦1.0.

It should also be understood that group IB, IIIA, and VIA elements other than Cu, In, Ga, Se, and S may be included in the description of the IB-IIIA-VIA alloys described herein, and that the use of a hyphen (“-”e.g., in Cu—Se or Cu—In—Se) does not indicate a compound, but rather indicates a coexisting mixture of the elements joined by the hyphen. It is also understood that group IB is sometimes referred to as group 11, group IIIA is sometimes referred to as group 13 and group VIA is sometimes referred to as group 16. Furthermore, elements of group VIA (16) are sometimes referred to as chalcogens. Where several elements can be combined with or substituted for each other, such as In and Ga, or Se, and S, in embodiments of the present invention, it is not uncommon in this art to include in a set of parentheses those elements that can be combined or interchanged, such as (In, Ga) or (Se, S). The descriptions in this specification sometimes use this convenience. Finally, also for convenience, the elements are discussed with their commonly accepted chemical symbols. Group IB elements suitable for use in the method of this invention include copper (Cu), silver (Ag), and gold (Au). Preferably the group IB element is copper (Cu). Group IIIA elements suitable for use in the method of this invention include gallium (Ga), indium (In), aluminum (Al), and thallium (Tl). Preferably the group IIIA element is gallium (Ga) or indium (In). Group VIA elements of interest include selenium (Se), sulfur (S), and tellurium (Te), and preferably the group VIA element is either Se and/or S.

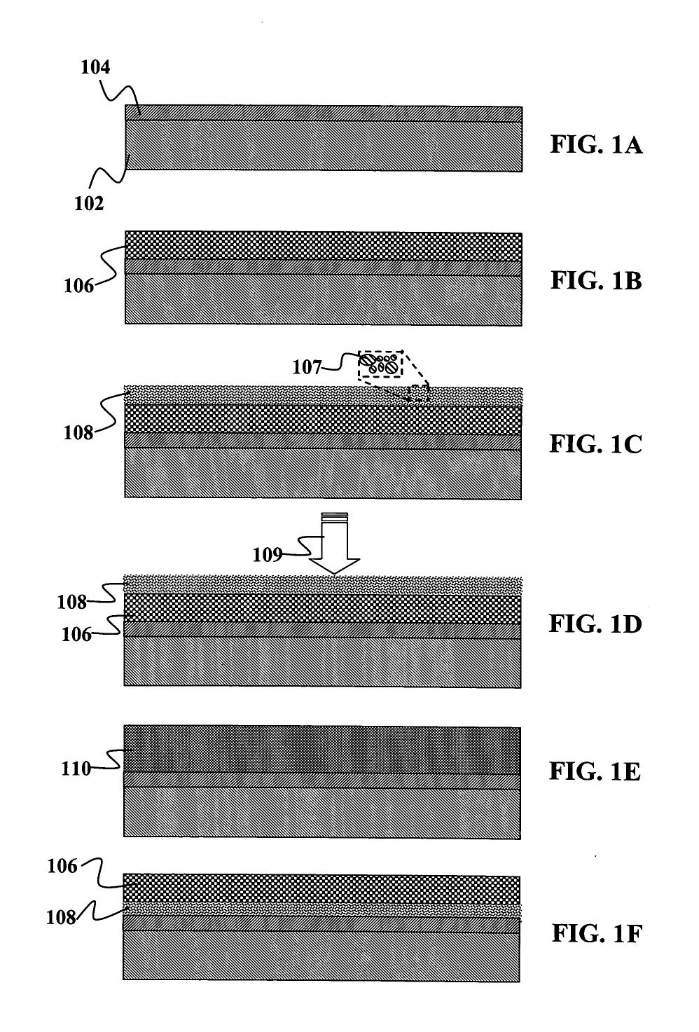

According to a first embodiment of the present invention, the compound layer may include one or more group IB elements and two or more different group IIIA elements as shown in FIGS. 1A-1E.

The absorber layer may be formed on a substrate 102, as shown in FIG. 1A. By way of the example, the substrate 102 may be made of a metal such as, but not limited to, aluminum. Depending on the material of the substrate 102, it may be useful to coat a surface of the substrate with a contact layer 104 to promote electrical contact between the substrate 102 and the absorber layer that is to be formed on it. For example, where the substrate 102 is made of aluminum the contact layer 104 may be a layer of molybdenum. For the purposes of the present discussion, the contact layer 104 may be regarded as being part of the substrate. As such, any discussion of forming or disposing a material or layer of material on the substrate 102 includes disposing or forming such material or layer on the contact layer 104, if one is used.

As shown in FIG. 1B, a precursor layer 106 is formed on the substrate. The precursor layer 106 contains one or more group IB elements and two or more different group IIIA elements. Preferably, the one or more group IB elements include copper, and the group IIIA elements include indium and gallium. By way of example, the precursor layer 106 may be a oxygen-free compound containing copper, indium and gallium. Preferably, the precursor layer is a compound of the form Cu_{z}InₓGa₁₋ₓ, where 0≦x≦1 and 0.5≦z≦1.5. Those of skill in the art will recognize that other group IB elements may be substituted for Cu and other group IIIA elements may be substituted for In and Ga. As one nonlimiting example, the precursor layer is between about 10 nm and about 5000 nm thick. In other embodiments, the precursor layer may be between about 2.0 to about 0.4 microns thick.

As shown in FIG. 1C, a layer 108 containing elemental chalcogen particles 107 over the precursor layer 106. By way of example, and without loss of generality, the chalcogen particles may be particles of selenium, sulfur or tellurium. As shown in FIG. 1D, heat 109 is applied to the precursor layer 106 and the layer 108 containing the chalcogen particles to heat them to a temperature sufficient to melt the chalcogen particles 107 and to react the chalcogen particles 107 with the group IB element and group IIIA elements in the precursor layer 106. The reaction of the chalcogen particles 107 with the group IB and IIIA elements forms a compound film 110 of a group IB-IIIA-chalcogenide compound as shown in FIG. 1E. Preferably, the group IB-IIIA-chalcogenide compound is of the form Cu_{z}In₁₋ₓGaₓSe_{2(1-y)}S_{y}, where 0<x<1, 0≦y≦1, and 0.5≦z≦1.5.

If the chalcogen particles 107 melt at a relatively low temperature (e.g., 220° C. for Se, 120° C. for S) the chalcogen is already in a liquid state and makes good contact with the group IB and IIIA nanoparticles in the precursor layer 106. If the precursor layer 106 and molten chalcogen are then heated sufficiently (e.g., at about 375° C.) the chalcogen reacts with the group IB and IIIA elements in the precursor layer 106 to form the desired IB-IIIA-chalcogenide material in the compound film 110. As one nonlimiting example, the precursor layer is between about 10 nm and about 5000 nm thick. In other embodiments, the precursor layer may be between about 4.0 to about 0.5 microns thick.

There are a number of different techniques for forming the IB-IIIA precursor layer 106. For example, the precursor layer 106 may be formed from a nanoparticulate film including nanoparticles containing the desired group IB and IIIA elements. The nanoparticles may be a mixture elemental nanoparticles, i.e., nanoparticles having only a single atomic species. Alternatively, the nanoparticles may be binary nanoparticles, e.g., Cu—In, In—Ga, or Cu—Ga or ternary particles, such as, but not limited to, Cu—In—Ga, or quaternary particles. Such nanoparticles may be obtained, e.g., by ball milling a commercially available powder of the desired elemental, binary or ternary material. These nanoparticles may be between about 0.1 nanometer and about 500 nanometers in size.

One of the advantages of the use of nanoparticle-based dispersions is that it is possible to vary the concentration of the elements within the compound film 110 either by building the precursor layer in a sequence of sub-layers or by directly varying the relative concentrations in the precursor layer 106. The relative elemental concentration of the nanoparticles that make up the ink for each sub-layer may be varied. Thus, for example, the concentration of gallium within the absorber layer may be varied as a function of depth within the absorber layer.

The layer 108 containing the chalcogen particles 107 may be disposed over the nanoparticulate film and the nanoparticulate film (or one or more of its constituent sub-layers) may be subsequently sintered in conjunction with heating the chalcogen particles 107. Alternatively, the nanoparticulate film may be sintered to form the precursor layer 106 before disposing the layer 108 containing elemental chalcogen particles 107 over precursor layer 106.

In one embodiment of the present invention, the nanoparticles in the nanoparticulate film used to form the precursor layer 106 contain no oxygen or substantially no oxygen other than those unavoidably present as impurities. The nanoparticulate film may be a layer of a dispersion, such as, but not limited to, an ink, paste, coating, or paint. The dispersion may include nanoparticles including group IB and IIIA elements in a solvent or other components. Chalcogens may be incidentally present in components of the nanoparticulate film other than the nanoparticles themselves. A film of the dispersion can be spread onto the substrate and annealed to form the precursor layer 106. By way of example the dispersion can be made by forming oxygen-free nanoparticles containing elements from group IB, group IIIA and intermixing these nanoparticles and adding them to a liquid. It should be understood that in some embodiments, the creation process for the particles and/or dispersion may include milling feedstock particles whereby the particles are already dispersed in a carrier liquid and/or dispersing agent. The precursor layer 106 may be formed using a variety of non-vacuum techniques such as but not limited to wet coating, spray coating, spin coating, doctor blade coating, contact printing, top feed reverse printing, bottom feed reverse printing, nozzle feed reverse printing, gravure printing, microgravure printing, reverse microgravure printing, comma direct printing, roller coating, slot die coating, meyerbar coating, lip direct coating, dual lip direct coating, capillary coating, ink-jet printing, jet deposition, spray deposition, and the like, as well as combinations of the above and/or related technologies. In one embodiment of the present invention, the precursor layer 106 may be built up in a sequence of sub-layers formed one on top of another in a sequence. The nanoparticulate film may be heated to drive off components of the dispersion that are not meant to be part of the film and to sinter the particles and to form the compound film. By way of example, nanoparticulate-based inks containing elements and/or solid solutions from groups IB and IIIA may be formed as described in commonly-assigned US Patent Application publication 20050183767, which has been incorporated herein by reference.

The nanoparticles making up the dispersion may be in a desired particle size range of between about 0.1 nm and about 500 nm in diameter, preferably between about 10 nm and about 300 nm in diameter, and more preferably between about 50 nm and 250 nm. In still other embodiments, the particles may be between about 200 nm and about 500 nm

In some embodiments, one or more group IIIA elements may be provided in molten form. For example, an ink may be made starting with a molten mixture of Gallium and/or Indium. Copper nanoparticles may then be added to the mixture, which may then be used as the ink/paste. Copper nanoparticles are also commercially available. Alternatively, the temperature of the Cu—Ga—In mixture may be adjusted (e.g. cooled) until a solid forms. The solid may be ground at that temperature until small nanoparticles (e.g., less than about 100 nm) are present.

In other embodiments of the invention, the precursor layer 106 may be fabricated by forming a molten mixture of one or more metals of group IIIA and metallic nanoparticles containing elements of group IB and coating the substrate with a film formed from the molten mixture. The molten mixture may include a molten group IIIA element containing nanoparticles of a group IB element and (optionally) another group IIIA element. By way of example nanoparticles containing copper and gallium may be mixed with molten indium to form the molten mixture. The molten mixture may also be made starting with a molten mixture of Indium and/or Gallium. Copper nanoparticles may then be added to the molten mixture. Copper nanoparticles are also commercially available. Alternatively, such nanoparticles can be produced using any of a variety of well-developed techniques, including but not limited to (i) electro-explosion of copper wire, (ii) mechanical grinding of copper particles for a sufficient time so as to produce nanoparticles, or (iii) solution-based synthesis of copper nanoparticles from organometallic precursors or reduction of copper salts. Alternatively, the temperature of a molten Cu—Ga—In mixture may be adjusted (e.g. cooled) until a solid forms. In one embodiment of the present invention, the solid may be ground at that temperature until particles of a target size are present. Additional details of this technique are described in commonly assigned US Patent Application publication 2005183768, which is incorporated herein by reference. Optionally, the selenium particles prior to melting may be less than 1 micron, less than 500 nm, less than 400 nm, less than 300 nm, less than 200 nm, and/or less than 100 nm.

In another embodiment, the IB-IIIA precursor layer 106 may be formed using a composition of matter in the form of a dispersion containing a mixture of elemental nanoparticles of the IB, the IIIA, dispersed with a suspension of nanoglobules of Gallium. Based on the relative ratios of input elements, the gallium nanoglobule-containing dispersion can then have a Cu/(In+Ga) compositional ratio ranging from 0.01 to 1.0 and a Ga/(In+Ga) compositional ratio ranging from 0.01 to 1.0. This technique is described in commonly-assigned U.S. patent application Ser. No. 11/081,163, which has been incorporated herein by reference.

Alternatively, the precursor layer 106 may be fabricated using coated nanoparticles as described in commonly-assigned U.S. patent application Ser. No. 10/943,657, which is incorporated herein by reference. Various coatings could be deposited, either singly, in multiple layers, or in alternating layers, all of various thicknesses. Specifically, core nanoparticles containing one or more elements from group IB and/or IIIA and/or VIA may be coated with one or more layers containing elements of group IB, IIIA or VIA to form coated nanoparticles. Preferably at least one of the layers contains an element that is different from one or more of the group IB, IIIA or VIA elements in the core nanoparticle. The group IB, IIIA and VIA elements in the core nanoparticle and layers may be in the form of pure elemental metals or alloys of two or more metals. By way of example, and without limitation, the core nanoparticles may include elemental copper, or alloys of copper with gallium, indium, or aluminum and the layers may be gallium, indium or aluminum. Using nanoparticles with a defined surface area, a layer thickness could be tuned to give the proper stoichiometric ratio within the aggregate volume of the nanoparticle. By appropriate coating of the core nanoparticles, the resulting coated nanoparticles can have the desired elements intermixed within the size scale of the nanoparticle, while the stoichiometry (and thus the phase) of the coated nanoparticle may be tuned by controlling the thickness of the coating(s).

In certain embodiments the precursor layer 106 (or selected constituent sub-layers, if any) may be formed by depositing a source material on the substrate to form a precursor, and heating the precursor to form a film. The source material may include Group IB-IIIA containing particles having at least one Group IB-IIIA phase, with Group IB-IIIA constituents present at greater than about 50 molar percent of the Group IB elements and greater than about 50 molar percent of the Group IIIA elements in the source material. Additional details of this technique are described in U.S. Pat. No. 5,985,691 to Basol which is incorporated herein by reference.

Alternatively, the precursor layer 106 (or selected constituent sub-layers, if any) may be made from a precursor film containing one or more phase-stabilized precursors in the form of fine particles comprising at least one metal oxide. The oxides may be reduced in a reducing atmosphere. In particular single-phase mixed-metal oxide particles with an average diameter of less than about 1 micron may be used for the precursor. Such particles can be fabricated by preparing a solution comprising Cu and In and/or Ga as metal-containing compounds; forming droplets of the solution; and heating the droplets in an oxidizing atmosphere. The heating pyrolyzes the contents of the droplets thereby forming single-phase copper indium oxide, copper gallium oxide or copper indium gallium oxide particles. These particles can then be mixed with solvents or other additives to form a precursor material which can be deposited on the substrate, e.g., by screen printing, slurry spraying or the like, and then annealed to form the sub-layer. Additional details of this technique are described in U.S. Pat. No. 6,821,559 to Eberspacher, which is incorporated herein by reference.

Alternatively, the precursor layer 106 (or selected constituent sub-layers, if any) may be deposited using a precursor in the form of a nano-powder material formulated with a controlled overall composition and having particles of one solid solution. The nano-powder material precursor may be deposited to form the first, second layer or subsequent sub-layers, and reacted in at least one suitable atmosphere to form the corresponding component of the active layer. The precursor may be formulated from a nano-powder, i.e. a powdered material with nano-meter size particles. Compositions of the particles constituting the nano-powder used in precursor formulation are important for the repeatability of the process and the quality of the resulting compound films. The particles making up the nano-powder are preferably near-spherical in shape and their diameters are less than about 200 nm, and preferably less than about 100 nm. Alternatively, the nano-powder may contain particles in the form of small platelets. The nano-powder preferably contains copper-gallium solid solution particles, and at least one of indium particles, indium-gallium solid-solution particles, copper-indium solid solution particles, and copper particles. Alternatively, the nano-powder may contain copper particles and indium-gallium solid-solution particles.

Any of the various nanoparticulate compositions described above may be mixed with well known solvents, carriers, dispersants etc. to prepare an ink or a paste that is suitable for deposition onto the substrate 102. Alternatively, nano-powder particles may be prepared for deposition on a substrate through dry processes such as, but not limited to, dry powder spraying, electrostatic spraying or processes which are used in copying machines and which involve rendering charge onto particles which are then deposited onto substrates. After precursor formulation, the precursor, and thus the nano-powder constituents may be deposited onto the substrate 102 in the form of a micro-layer, e.g., using dry or wet processes. Dry processes include electrostatic powder deposition approaches where the prepared powder particles may be coated with poorly conducting or insulating materials that can hold charge. Examples of wet processes include screen printing, ink jet printing, ink deposition by doctor-blading, reverse roll coating etc. In these approaches the nano-powder may be mixed with a carrier which may typically be a water-based or organic solvent, e.g., water, alcohols, ethylene glycol, etc. The carrier and other agents in the precursor formulation may be totally or substantially evaporated away to form the micro-layer on the substrate. The micro-layer can subsequently be reacted to form the sub-layer. The reaction may involve an annealing process, such as, but not limited to, furnace-annealing, RTP or laser-annealing, microwave annealing, among others. Annealing temperatures may be between about 350° C. to about 600° C. and preferably between about 400° C. to about 550° C. The annealing atmosphere may be inert, e.g., nitrogen or argon. Alternatively, the reaction step may employ an atmosphere with a vapor containing at least one Group VIA element (e.g., Se, S, or Te) to provide a desired level of Group VIA elements in the absorber layer. Further details of this technique are described in US Patent Application Publication 20040219730 to Bulent Basol, which is incorporated herein by reference.

In certain embodiments of the invention, the precursor layer 106 (or any of its sub-layers) may be annealed, either sequentially or simultaneously. Such annealing may be accomplished by rapid heating of the substrate 102 and precursor layer 106 from an ambient temperature to a plateau temperature range of between about 200° C. and about 600° C. The temperature is maintained in the plateau range for a period of time ranging between about a fraction of a second to about 60 minutes, and subsequently reduced. Alternatively, the annealing temperature could be modulated to oscillate within a temperature range without being maintained at a particular plateau temperature. This technique (referred to herein as rapid thermal annealing or RTA) is particularly suitable for forming photovoltaic active layers (sometimes called “absorber” layers) on metal foil substrates, such as, but not limited to, aluminum foil. Additional details of this technique are described in U.S. patent application Ser. No. 10/943,685, which is incorporated herein by reference.

Other alternative embodiments of the invention utilize techniques other than printing processes to form the absorber layer. For example, a group IB and/or group IIIA elements may be deposited onto the top surface of a substrate and/or onto the top surface of one or more of the sub-layers of the active layer by atomic layer deposition (ALD). For example a thin layer of Ga may be deposited by ALD at the top of a stack of sub-layers formed by printing techniques. By use of ALD, copper, indium, and gallium, may be deposited in a precise stoichiometric ratio that is intermixed at or near the atomic level. Furthermore, by changing sequence of exposure pulses for each precursor material, the relative composition of Cu, In, Ga and Se or S within each atomic layer can be systematically varied as a function of deposition cycle and thus depth within the absorber layer. Such techniques are described in US Patent Application Publication 20050186342, which is incorporated herein by reference. Alternatively, the top surface of a substrate could be coated by using any of a variety of vacuum-based deposition techniques, including but not limited to sputtering, evaporation, chemical vapor deposition, physical vapor deposition, electron-beam evaporation, and the like.

The chalcogen particles 107 in the layer 108 may be between about 1 nanometer and about 50 microns in size, preferably between about 100 nm and 10 microns, more preferably between about 100 nm and 1 micron, and most preferably between about 150 and 300 nm. It is noted that the chalcogen particles 107 may be larger than the final thickness of the IB-IIIA-VIA compound film 110. The chalcogen particles 107 may be mixed with solvents, carriers, dispersants etc. to prepare an ink or a paste that is suitable for wet deposition over the precursor layer 106 to form the layer 108. Alternatively, the chalcogen particles 107 may be prepared for deposition on a substrate through dry processes to form the layer 108. It is also noted that the heating of the layer 108 containing chalcogen particles 107 may be carried out by an RTA process, e.g., as described above.

The chalcogen particles 107 (e.g., Se or S) may be formed in several different ways. For example, Se or S particles may be formed starting with a commercially available fine mesh powder (e.g., 200 mesh/75 micron) and ball milling the powder to a desirable size. A typical ball milling procedure may use a ceramic milling jar filled with grinding ceramic balls and a feedstock material, which may be in the form of a powder, in a liquid medium. When the jar is rotated or shaken, the balls shake and grind the powder in the liquid medium to reduce the size of the particles of the feedstock material. Optionally, ball mills with specially designed agitator may be used to move the beads into the material to be processed.

Examples of chalcogen powders and other feedstocks commercially available are listed in Table I below.

TABLE I

| Chemical | Formula | Typical % Purity |
|---|---|---|
| Selenium metal | Se | 99.99 |
| Selenium metal | Se | 99.6 |
| Selenium metal | Se | 99.6 |
| Selenium metal | Se | 99.999 |
| Selenium metal | Se | 99.999 |
| Sulfur | S | 99.999 |
| Tellurium metal | Te | 99.95 |
| Tellurium metal | Te | 99.5 |
| Tellurium metal | Te | 99.5 |
| Tellurium metal | Te | 99.9999 |
| Tellurium metal | Te | 99.99 |
| Tellurium metal | Te | 99.999 |
| Tellurium metal | Te | 99.999 |
| Tellurium metal | Te | 99.95 |
| Tellurium metal | Te | 99.5 |

Se or S particles may alternatively be formed using an evaporation-condensation method. Alternatively, Se or S feedstock may be melted and sprayed (“atomization”) to form droplets that solidify into nanoparticles.

The chalcogen particles 107 may also be formed using a solution-based technique, which also is called a “Top-Down” method (Nano Letters, 2004 Vol. 4, No. 10 2047-2050 “Bottom-Up and Top-Down Approaches to Synthesis of Monodispersed Spherical Colloids of low Melting-Point Metals”—Yuliang Wang and Younan Xia). This technique allows processing of elements with melting points below 400° C. as monodispersed spherical colloids, with diameter controllable from 100 nm to 600 nm, and in copious quantities. For this technique, chalcogen (Se or S) powder is directly added to boiling organic solvent, such as di(ethylene glycol,) and melted to produce droplets. After the reaction mixture had been vigorously stirred and thus emulsified for 20 min, uniform spherical colloids of metal obtained as the hot mixture is poured into a cold organic solvent bath (e.g. ethanol) to solidify the chalcogen (Se or Se) droplets.

Referring now to FIG. 1F, it should also be understood that in some embodiments of the present invention, the layer 108 of chalcogen particles may be formed below the precursor layer 106. This position of the layer 108 still allows the chalcogen particles to provide a sufficient surplus of chalcogen to the precursor layer 106 to fully react with the group IB and group IIIA elements in layer 106. Additionally, since the chalcogen released from the layer 108 may be rising through the layer 106, this position of the layer 108 below layer 106 may be beneficial to generate greater intermixing between elements. The thickness of the layer 108 may be in the range of about 10 nm to about 5 microns. In other embodiments, the thickness of the layer 108 may be in the range of about 4.0 microns to about 0.5 microns.

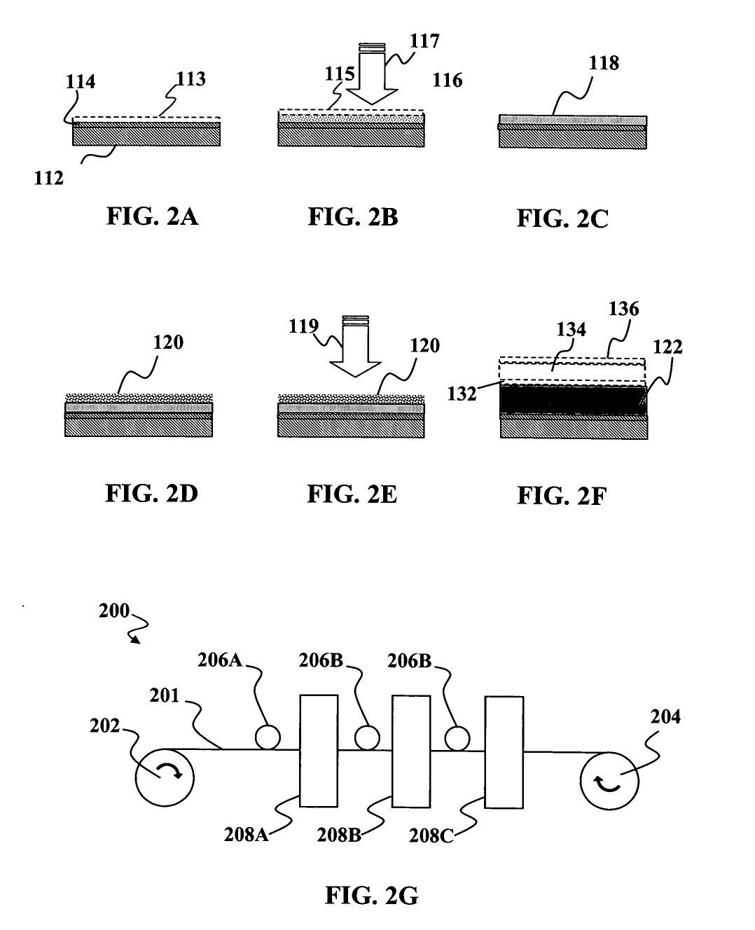

According to a second embodiment of the present invention, the compound layer may include one or more group IB elements and one or more group IIIA elements. Fabrication may proceed as illustrated in FIGS. 2A-2F. The absorber layer may be formed on a substrate 112, as shown in FIG. 2A. A surface of the substrate 112, may be coated with a contact layer 114 to promote electrical contact between the substrate 112 and the absorber layer that is to be formed on it. By way of example, an aluminum substrate 112 may be coated with a contact layer 114 of molybdenum. As discussed above, forming or disposing a material or layer of material on the substrate 112 includes disposing or forming such material or layer on the contact layer 114, if one is used. Optionally, it should also be understood that a layer 115 may also be formed on top of contact layer 114 and/or directly on substrate 112. This layer may be solution coated, evaporated, and/or deposited using vacuum based techniques. Although not limited to the following, the layer 115 may have a thickness less than that of the precursor layer 116. In one nonlimiting example, the layer may be between about 1 to about 100 nm in thickness. The layer 115 may be comprised of various materials including but not limited to at least one of the following: a group IB element, a group IIIA element, a group VIA element, a group IA element (new style: group 1), a binary and/or multi-nary alloy of any of the preceding elements, a solid solution of any of the preceding elements, copper, indium, gallium, selenium, copper indium, copper gallium, indium gallium, sodium, a sodium compound, sodium fluoride, sodium indium sulfide, copper selenide, copper sulfide, indium selenide, indium sulfide, gallium selenide, gallium sulfide, copper indium selenide, copper indium sulfide, copper gallium selenide, copper gallium sulfide, indium gallium selenide, indium gallium sulfide, copper indium gallium selenide, and/or copper indium gallium sulfide.

As shown in FIG. 2B, a precursor layer 116 is formed on the substrate. The precursor layer 116 contains one or more group IB elements and one or more group IIIA elements. Preferably, the one or more group IB elements include copper. The one or more group IIIA elements may include indium and/or gallium. The precursor layer may be formed from a nanoparticulate film, e.g., using any of the techniques described above. In some embodiments, the particles may be particles that are substantially oxygen-free, which may include those that include less than about 1 wt % of oxygen. Other embodiments may use materials with less than about 5 wt % of oxygen. Still other embodiments may use materials with less than about 3 wt % oxygen. Still other embodiments may use materials with less than about 2 wt % oxygen. Still other embodiments may use materials with less than about 0.5 wt % oxygen. Still other embodiments may use materials with less than about 0.1 wt % oxygen.

Optionally, as seen in FIG. 2B, it should also be understood that a layer 117 may also be formed on top of precursor layer 116. It should be understood that the stack may have both layers 115 and 117, only one of the layers, or none of the layers. Although not limited to the following, the layer 117 may have a thickness less than that of the precursor layer 116. In one nonlimiting example, the layer may be between about 1 to about 100 nm in thickness. The layer 117 may be comprised of various materials including but not limited to at least one of the following: a group IB element, a group IIIA element, a group VIA element, a group IA element (new style: group 1), a binary and/or multinary alloy of any of the preceding elements, a solid solution of any of the preceding elements, copper, indium, gallium, selenium, copper indium, copper gallium, indium gallium, sodium, a sodium compound, sodium fluoride, sodium indium sulfide, copper selenide, copper sulfide, indium selenide, indium sulfide, gallium selenide, gallium sulfide, copper indium selenide, copper indium sulfide, copper gallium selenide, copper gallium sulfide, indium gallium selenide, indium gallium sulfide, copper indium gallium selenide, and/or copper indium gallium sulfide.

In one embodiment, the precursor layer 116 may be formed by other means, such as, but not limited to, evaporation, sputtering, ALD, etc. By way of example, the precursor layer 116 may be a oxygen-free compound containing copper, indium and gallium. Heat 117 is applied to sinter the precursor layer 116 into a group IB-IIIA compound film 118 as shown in FIGS. 2B-2C. The heat 117 may be supplied in a rapid thermal annealing process, e.g., as described above. Specifically, the substrate 112 and precursor layer 116 may be heated from an ambient temperature to a plateau temperature range of between about 200° C. and about 600° C. The temperature is maintained in the plateau range for a period of time ranging between about a fraction of a second to about 60 minutes, and subsequently reduced.

As shown in FIG. 2D, a layer 120 containing elemental chalcogen particles over the precursor layer 116. By way of example, and without loss of generality, the chalcogen particles may be particles of selenium, sulfur or tellurium. Such particles may be fabricated as described above. The chalcogen particles in the layer 120 may be between about 1 nanometer and about 25 microns in size. The chalcogen particles may be mixed with solvents, carriers, dispersants etc. to prepare an ink or a paste that is suitable for wet deposition over the precursor layer 116 to form the layer 120. Alternatively, the chalcogen particles may be prepared for deposition on a substrate through dry processes to form the layer 120.

As shown in FIG. 2E, heat 119 is applied to the precursor layer 116 and the layer 120 containing the chalcogen particles to heat them to a temperature sufficient to melt the chalcogen particles and to react the chalcogen particles with the group IB element and group IIIA elements in the precursor layer 116. The heat 119 may be applied in a rapid thermal annealing process, e.g., as described above. The reaction of the chalcogen particles with the group IB and IIIA elements forms a compound film 122 of a group IB-IIIA-chalcogenide compound as shown in FIG. 2F. The group IB-IIIA-chalcogenide compound is of the form Cu_{z}In₁₋ₓGaₓSe_{2(1-y)}S_{y}, where 0≦x≦1, 0≦y≦1, 0.5≦z≦1.5.

Referring still to FIGS. 2A-2F, it should be understood that sodium may also be used with the precursor material to improve the qualities of the resulting film. In a first method, as discussed in regards to FIGS. 2A and 2B, one or more layers of a sodium containing material may be formed above and/or below the precursor layer 116. The formation may occur by solution coating and/or other techniques such as but not limited to sputtering, evaporation, CBD, electroplating, sol-gel based coating, spray coating, chemical vapor deposition (CVD), physical vapor deposition (PVD), atomic layer deposition (ALD), and the like.

Optionally, in a second method, sodium may also be introduced into the stack by sodium doping the particles in the precursor layer 116. As a nonlimiting example, the chalcogenide particles and/or other particles in the precursor layer 116 may be a sodium containing material such as, but not limited to, Cu—Na, In—Na, Ga—Na, Cu—In—Na, Cu—Ga—Na, In—Ga—Na, Na—Se, Cu—Se—Na, In—Se—Na, Ga—Se—Na, Cu—In—Se—Na, Cu—Ga—Se—Na, In—Ga—Se—Na, Cu—In—Ga—Se—Na, Na—S, Cu—S—Na, In—S—Na, Ga—S—Na, Cu—In—S—Na, Cu—Ga—S—Na, In—Ga—S—Na, and/or Cu—In—Ga—S—Na. In one embodiment of the present invention, the amount of sodium in the chalcogenide particles and/or other particles may be about 1 at.% or less. In another embodiment, the amount of sodium may be about 0.5 at.% or less. In yet another embodiment, the amount of sodium may be about 0.1 at.% or less. It should be understood that the doped particles and/or flakes may be made by a variety of methods including milling feedstock material with the sodium containing material and/or elemental sodium.

Optionally, in a third method, sodium may be incorporated into the ink itself, regardless of the type of particle, nanoparticle, microflake, and/or nanoflakes dispersed in the ink. As a nonlimiting example, the ink may include particles (Na doped or undoped) and a sodium compound with an organic counter-ion (such as but not limited to sodium acetate) and/or a sodium compound with an inorganic counter-ion (such as but not limited to sodium sulfide). It should be understood that sodium compounds added into the ink (as a separate compound), might be present as particles (e.g. nanoparticles), or dissolved. The sodium may be in “aggregate” form of the sodium compound (e.g. dispersed particles), and the “molecularly dissolved” form.

None of the three aforementioned methods are mutually exclusive and may be applied singly or in any single or multiple combination to provide the desired amount of sodium to the stack containing the precursor material. Additionally, sodium and/or a sodium containing compound may also be added to the substrate (e.g. into the molybdenum target). Also, sodium-containing layers may be formed in between one or more precursor layers if multiple precursor layers (using the same or different materials) are used. It should also be understood that the source of the sodium is not limited to those materials previously listed. As a nonlimiting example, basically, any deprotonated alcohol where the proton is replaced by sodium, any deprotonated organic and inorganic acid, the sodium salt of the (deprotonated) acid, NaₓH_{y}Se_{z}SᵤTeᵥO_{w} where x, y, z, u, v, and w≧0, NaₓCu_{y}In_{z}GaᵤOᵥ where x, y, z, u, and v≧0, sodium hydroxide, sodium acetate, and the sodium salts of the following acids: butanoic acid, hexanoic acid, octanoic acid, decanoic acid, dodecanoic acid, tetradecanoic acid, hexadecanoic acid, 9-hexadecenoic acid, octadecanoic acid, 9-octadecenoic acid, 11-octadecenoic acid, 9,12-octadecadienoic acid, 9,12,15-octadecatrienoic acid, and/or 6,9,12-octadecatrienoic acid.

Optionally, as seen in FIG. 2F, it should also be understood that sodium and/or a sodium compound may be added to the processed chalcogenide film after the precursor layer has been sintered or otherwise processed. This embodiment of the present invention thus modifies the film after CIGS formation. With sodium, carrier trap levels associated with the grain boundaries are reduced, permitting improved electronic properties in the film. A variety of sodium containing materials such as those listed above may be deposited as layer 132 onto the processed film and then annealed to treat the CIGS film.

Additionally, the sodium material may be combined with other elements that can provide a bandgap widening effect. Two elements which would achieve this include gallium and sulfur. The use of one or more of these elements, in addition to sodium, may further improve the quality of the absorber layer. The use of a sodium compound such as but not limited to Na₂S, NaInS₂, or the like provides both Na and S to the film and could be driven in with an anneal such as but not limited to an RTA step to provide a layer with a bandgap different from the bandgap of the unmodified CIGS layer or film.

Referring now to FIG. 2G, it should be understood that embodiments of the invention are also compatible with roll-to-roll manufacturing. Specifically, in a roll-to-roll manufacturing system 200 a flexible substrate 201, e.g., aluminum foil travels from a supply roll 202 to a take-up roll 204. In between the supply and take-up rolls, the substrate 201 passes a number of applicators 206A, 206B, 206C, e.g. microgravure rollers and heater units 208A, 208B, 208C. Each applicator deposits a different layer or sub-layer of a photovoltaic device active layer, e.g., as described above. The heater units are used to anneal the different sub-layers. In the example depicted in FIG. 2G, applicators 206A and 206B may apply different sub-layers of a precursor layer (such as precursor layer 106 or precursor layer 116). Heater units 208A and 208B may anneal each sub-layer before the next sub-layer is deposited. Alternatively, both sub-layers may be annealed at the same time. Applicator 206C may apply a layer of material containing chalcogen particles as described above. Heater unit 208C heats the chalcogen layer and precursor layer as described above. Note that it is also possible to deposit the precursor layer (or sub-layers) then deposit the chalcogen-containing layer and then heat all three layers together to form the IB-IIIA-chalcogenide compound film used for the photovoltaic absorber layer.

The total number of printing steps can be modified to construct absorber layers with bandgaps of differential gradation. For example, additional films (fourth, fifth, sixth, and so forth) can be printed (and optionally annealed between printing steps) to create an even more finely-graded bandgap within the absorber layer. Alternatively, fewer films (e.g. double printing) can also be printed to create a less finely-graded bandgap.

Alternatively multiple layers can be printed and reacted with chalcogen before deposition of the next layer, as seen in FIG. 2F. One nonlimiting example would be to deposit a Cu—In—Ga layer, anneal it, then deposit a Se layer then treat that with RTA, follow that up by depositing another precursor layer 134 rich in Ga followed by another deposition of an Se layer 136 finished by a second RTA treatment. The embodiment may or may not have the layer 132, in which case if it does not, layer 134 will rest directly on layer 122. More generically, one embodiment of the method comprises depositing a precursor layer, annealing it, depositing a non-oxygen chalcogen layer, treating the combination with RTA, forming at least a second precursor layer (possibly with precursor materials different from those in the first precursor layer) on the existing layers, depositing another non-oxygen chalcogen layer, and treating the combination with RTA. This sequence may be repeated to build multiple sets of precursor layers or precursor layer/chalcogen layer combinations (depending on whether a heating step is used after each layer).

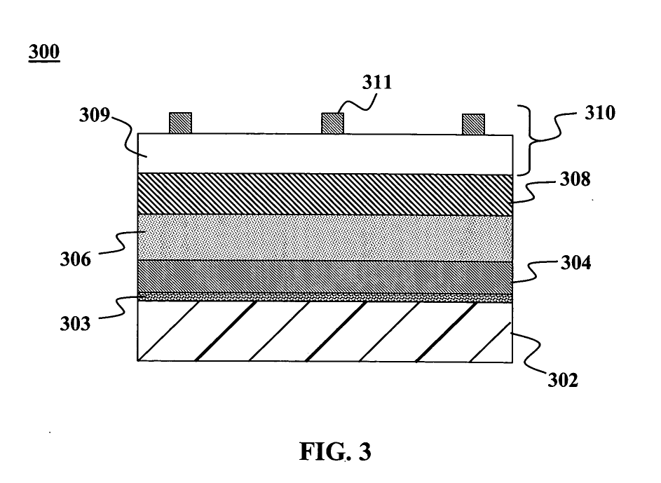

The compound films 110, 122 fabricated as described above may serve as absorber layers in photovoltaic devices. An example of such a photovoltaic device 300 is shown in FIG. 3. The device 300 includes a base substrate 302, an optional adhesion layer 303, a base electrode 304, an absorber layer 306 incorporating a compound film of the type described above, a window layer 308 and a transparent electrode 310. By way of example, the base substrate 302 may be made of a metal foil, a polymer such as polyimides (PI), polyamides, polyetheretherketone (PEEK), Polyethersulfone (PES), polyetherimide (PEI), polyethylene naphtalate (PEN), Polyester (PET), related polymers, or a metallized plastic. The base electrode 304 is made of an electrically conducive material. By way of example, the base electrode 304 may be of a metal layer whose thickness may be selected from the range of about 0.1 micron to about 25 microns. An optional intermediate layer 303 may be incorporated between the electrode 304 and the substrate 302. The transparent electrode 310 may include a transparent conductive layer 309 and a layer of metal (e.g., Al, Ag or Ni) fingers 311 to reduce sheet resistance.

The window layer 308 serves as a junction partner between the compound film and the transparent conducting layer 309. By way of example, the window layer 308 (sometimes referred to as a junction partner layer) may include inorganic materials such as cadmium sulfide (CdS), zinc sulfide (ZnS), zinc hydroxide, zinc selenide (ZnSe), n-type organic materials, or some combination of two or more of these or similar materials, or organic materials such as n-type polymers and/or small molecules. Layers of these materials may be deposited, e.g., by chemical bath deposition (CBD) or chemical surface deposition, to a thickness ranging from about 2 nm to about 1000 nm, more preferably from about 5 nm to about 500 nm, and most preferably from about 10 nm to about 300 nm.

The transparent conductive layer 309 may be inorganic, e.g., a transparent conductive oxide (TCO) such as indium tin oxide (ITO), fluorinated indium tin oxide, zinc oxide (ZnO) or aluminum doped zinc oxide, or a related material, which can be deposited using any of a variety of means including but not limited to sputtering, evaporation, CBD, electroplating, sol-gel based coating, spray coating, chemical vapor deposition (CVD), physical vapor deposition (PVD), atomic layer deposition (ALD), and the like. Alternatively, the transparent conductive layer may include a transparent conductive polymeric layer, e.g. a transparent layer of doped PEDOT (Poly-3,4-Ethylenedioxythiophene), carbon nanotubes or related structures, or other transparent organic materials, either singly or in combination, which can be deposited using spin, dip, or spray coating, and the like. Combinations of inorganic and organic materials can also be used to form a hybrid transparent conductive layer. Examples of such a transparent conductive layer are described e.g., in commonly-assigned US Patent Application Publication Number 20040187917, which is incorporated herein by reference.

Those of skill in the art will be able to devise variations on the above embodiments that are within the scope of these teachings. For example, it is noted that in embodiments of the present invention, the IB-IIIA precursor layers (or certain sub-layers of the precursor layers) may be deposited using techniques other than nanoparticulate-based inks. For example precursor layers or constituent sub-layers may be deposited using any of a variety of alternative deposition techniques including but not limited to vapor deposition techniques such as ALD, evaporation, sputtering, CVD, PVD, electroplating and the like.

By using a particulate chalcogen layer disposed over a IB-IIIA precursor film, slow and costly vacuum deposition steps (e.g., evaporation, sputtering) may be avoided. Embodiments of the present invention may thus leverage the economies of scale associated with printing techniques in general and roll-to-roll printing techniques in particular. Thus photovoltaic devices may be manufactured quickly, inexpensively and with high throughput.

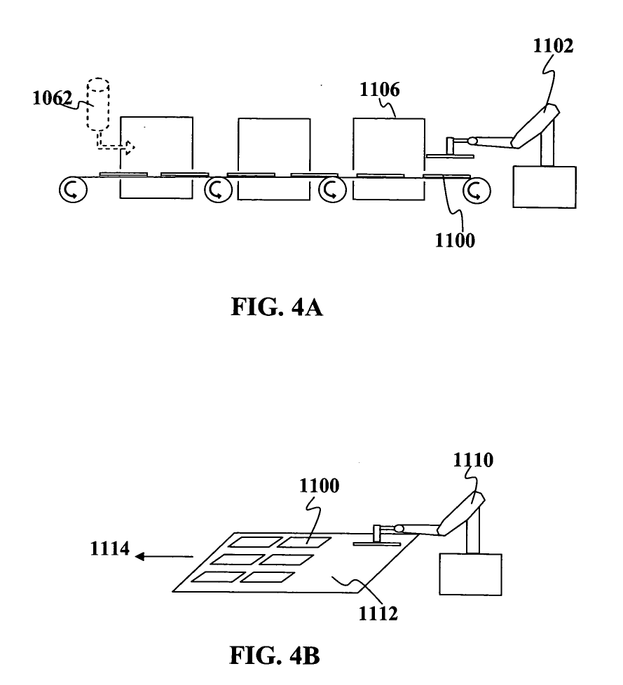

Referring now to FIG. 4A, it should also be understood that the embodiments of the present invention may also be used on a rigid substrate 1100. By way of nonlimiting example, the rigid substrate 1100 may be glass, soda-lime glass, steel, stainless steel, aluminum, polymer, ceramic, coated polymer, or other rigid material suitable for use as a solar cell or solar module substrate. A high speed pick-and-place robot 1102 may be used to move rigid substrates 1100 onto a processing area from a stack or other storage area. In FIG. 4A, the substrates 1100 are placed on a conveyor belt which then moves them through the various processing chambers. Optionally, the substrates 1100 may have already undergone some processing by the time and may already include a precursor layer on the substrate 1100. Other embodiments of the invention may form the precursor layer as the substrate 1100 passes through the chamber 1106.

FIG. 4B shows another embodiment of the present system where a pick-and-place robot 1110 is used to position a plurality of rigid substrates on a carrier device 1112 which may then be moved to a processing area as indicated by arrow 1114. This allows for multiple substrates 1100 to be loaded before they are all moved together to undergo processing.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, it should be understood that any of the above particles may be spherical, spheroidal, or other shaped. For any of the above embodiments, it should be understood that the use of core-shell particles and printed layers of a chalcogen source may be combined as desired to provide excess amounts of chalcogen. The layer of the chalcogen source may be above, below, or mixed with the layer containing the core-shell particles. With any of the above embodiments, it should be understood that chalcogen such as but not limited to selenium may added to, on top of, or below an elemental and non-chalcogen alloy precursor layer. Optionally, the materials in this precursor layer are oxygen-free or substantially oxygen free.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a size range of about 1 nm to about 200 nm should be interpreted to include not only the explicitly recited limits of about 1 nm and about 200 nm, but also to include individual sizes such as 2 nm, 3 nm, 4 nm, and sub-ranges such as 10 nm to 50 nm, 20 nm to 100 nm, etc. . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited.

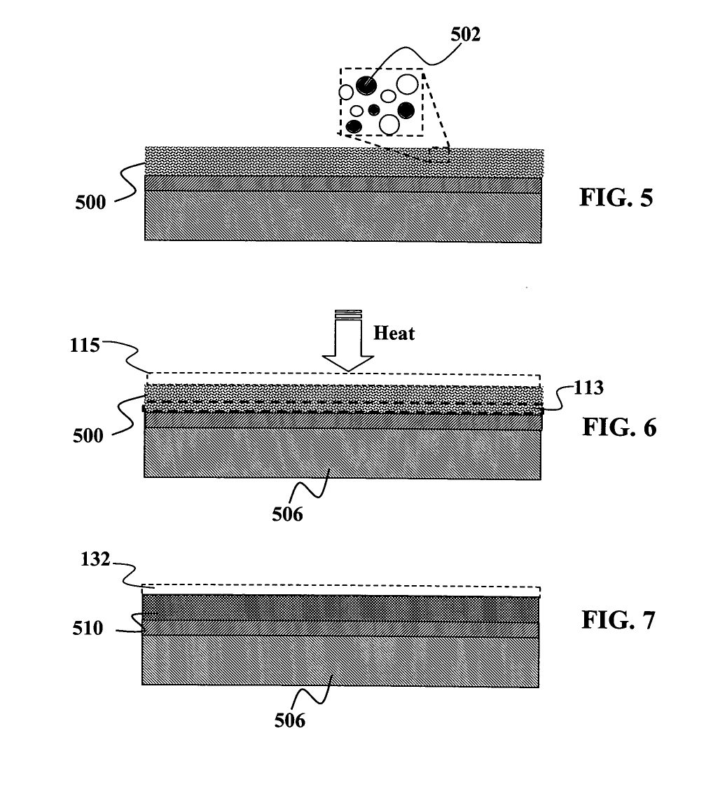

Referring now to FIG. 5, yet another embodiment of the present invention will now be described. In one embodiment, the particles used to form a precursor layer 500 may include particles that are inter-metallic particles 502. In one embodiment, an inter-metallic material is a material containing at least two elements, wherein the amount of one element in the inter-metallic material is less than about 50 molar percent of the total molar amount of the inter-metallic material and/or the total molar amount of that one element in a precursor material. The amount of the second element is variable and may range from less than about 50 molar percent to about 50 or more molar percent of the inter-metallic material and/or the total molar amount of that one element in a precursor material. Alternatively, inter-metallic phase materials may be comprised of two or more metals where the materials are admixed in a ratio between the upper bound of the terminal solid solution and an alloy comprised of about 50% of one of the elements in the inter-metallic material. The particle distribution shown in the enlarged view of FIG. 5 is purely exemplary and is nonlimiting. It should be understood that some embodiments may have particles that all contain inter-metallic materials, mixture of metallic and inter-metallic materials, metallic particles and inter-metallic particles, or combinations thereof.

It should be understood that inter-metallic phase materials are compounds and/or intermediate solid solutions containing two or more metals, which have characteristic properties and crystal structures different from those of either the pure metals or the terminal solid solutions. Inter-metallic phase materials arise from the diffusion of one material into another via crystal lattice vacancies made available by defects, contamination, impurities, grain boundaries, and mechanical stress. Upon two or more metals diffusing into one another, intermediate metallic species are created that are combinations of the two materials. Sub-types of inter-metallic compounds include both electron and interstitial compounds.

Electron compounds arise if two or more mixed metals are of different crystal structure, valency, or electropositivity relative to one another; examples include but are not limited to copper selenide, gallium selenide, indium selenide, copper telluride, gallium telluride, indium telluride, and similar and/or related materials and/or blends or mixtures of these materials.

Interstitial compounds arise from the admixture of metals or metals and non-metallic elements, with atomic sizes that are similar enough to allow the formation of interstitial crystal structures, where the atoms of one material fit into the spaces between the atoms of another material. For inter-metallic materials where each material is of a single crystal phase, two materials typically exhibit two diffraction peaks, each representative of each individual material, superimposed onto the same spectra. Thus inter-metallic compounds typically contain the crystal structures of both materials contained within the same volume. Examples include but are not limited to Cu—Ga, Cu—In, and similar and/or related materials and/or blends or mixtures of these materials, where the compositional ratio of each element to the other places that material in a region of its phase diagram other than that of the terminal solid solution.

Inter-metallic materials are useful in the formation of precursor materials for CIGS photovoltaic devices in that metals interspersed in a highly homogenous and uniform manner amongst one another, and where each material is present in a substantially similar amount relative to the other, thus allowing for rapid reaction kinetics leading to high quality absorber films that are substantially uniform in all three dimensions and at the nano-, micro, and meso-scales.

In the absence of the addition of indium nanoparticles, which are difficult to synthesize and handle, terminal solid solutions do not readily allow a sufficiently large range of precursor materials to be incorporated into a precursor film in the correct ratio (e.g. Cu/(In+Ga) =0.85) to provide for the formation of a highly light absorbing, photoactive absorber layer. Furthermore, terminal solid solutions may have mechanical properties that differ from those of inter-metallic materials and/or intermediate solid solutions (solid solutions between a terminal solid solution and/or element). As a nonlimiting example, some terminal solid solutions are not brittle enough to be milled for size reduction. Other embodiments may be too hard to be milled. The use of inter-metallic materials and/or intermediate solid solutions can address some of these drawbacks.

The advantages of particles 502 having an inter-metallic phase are multi-fold. As a nonlimiting example, a precursor material suitable for use in a thin film solar cell may contain group IB and group IIIA elements such as copper and indium, respectively. If an inter-metallic phase of Cu—In is used such as Cu₁In₂, then Indium is part of an In-rich Cu material and not added as pure indium. Adding pure indium as a metallic particle is challenging due to the difficulty in achieving In particle synthesis with high yield, small and narrow nanoparticle size distribution, and requiring particle size discrimination, which adds further cost. Using inter-metallic In-rich Cu particles avoids pure elemental In as a precursor material. Additionally, because the inter-metallic material is Cu poor, this also advantageously allows Cu to be added separately to achieve precisely the amount of Cu desired in the precursor material. The Cu is not tied to the ratio fixed in alloys or solid solutions that can be created by Cu and In. The inter-metallic material and the amount of Cu can be fine tuned as desired to reach a desired stoichiometric ratio. Ball milling of these particles results in no need for particle size discrimination, which decreases cost and improves the throughput of the material production process.

In some specific embodiments of the present invention, having an inter-metallic material provides a broader range of flexibility. Since economically manufacturing elemental indium particles is difficult, it would be advantageous to have an indium-source that is more economically interesting. Additionally, it would be advantageous if this indium source still allows varying both the Cu/(In+Ga) and Ga/(In+Ga) in the layer independently of each other. As one nonlimiting example, a distinction can be made between Cu₁₁In₉ and Cu₁In₂ with an inter-metallic phase. This particularly true if only one layer of precursor material is used. If, for this particular example, if indium is only provided by Cu₁₁In₉, there is more restriction what stoichiometric ratio can be created in a final group IB-IIIA-VIA compound. With Cu₁In₂ as the only indium source, however, there is much greater range of ratio can be created in a final group IB-IIIA-VIA compound. Cu₁In₂ allows you to vary both the Cu/(In+Ga) and Ga/(In+Ga) independently in a broad range, whereas Cu11In9 does not. For instance, Cu11In9 does only allow for Ga/(In+Ga)=0.25 with Cu/(In+Ga)>0.92. Yet another example, Cu11In9 does only allow for Ga/(In+Ga)=0.20 with Cu/(In+Ga)>0.98. Yet another example, Cu11In9 does only allow for Ga/(In+Ga)=0.15 with Cu/(In+Ga)>1.04. Thus for an intermetallic material, particularly when the intermetallic material is a sole source of one of the elements in the final compound, the final compound may be created with stoichiometric ratios that more broadly explore the bounds of Cu/(In+Ga) with a compositional range of about 0.7 to about 1.0, and Ga/(In+Ga) with a compositional range of about 0.05 to about 0.3 In other embodiments, Cu/(In+Ga) compositional range may be about 0.01 to about 1.0. In other embodiments, the Cu/(In+Ga) compositional range may be about 0.01 to about 1.1. In other embodiments, the Cu/(In+Ga) compositional range may be about 0.01 to about 1.5. This typically results in additional CuₓSe_{y} which we might be able to remove afterwards if it is at the top surface.

Furthermore, it should be understood that during processing, an intermetallic material may create more liquid than other compounds. As a nonlimiting example, Cu₁In₂ will form more liquid when heated during processing than Cu11In9. More liquid promotes more atomic intermixing since it easier for material to move and mix while in a liquid stage.

Additionally, there are specific advantages for particular types of inter-metallic particles such as, but not limited to, Cu₁In₂. Cu₁In₂ is a material that is metastable. The material is more prone to decomposition, which advantageously for the present invention, will increase the rate of reaction (kinetically). Further, the material is less prone to oxidation (e.g. compared to pure In) and this further simplifies processing. This material may also be single-phase, which would make it more uniform as a precursor material resulting in better yield.

As seen in FIGS. 6 and 7, after the layer 500 is deposited over the substrate 506, it may then be heated in a suitable atmosphere to react the layer 500 in FIG. 6 and form film 510 shown in FIG. 7. It should be understood that the layer 500 may be used in conjunction with layers 113 and 115 as described above with regards to FIG. 2A and 2B. The layer 113 may be comprised of various materials including but not limited at least one of the following: a group IB element, a group IIIA element, a group VIA element, a group IA element (new style: group 1), a binary and/or multinary alloy of any of the preceding elements, a solid solution of any of the preceding elements. It should be understood that sodium or a sodium-based material such as but not limited to sodium, a sodium compound, sodium fluoride, and/or sodium indium sulfide, may also be used in layer 113 with the precursor material to improve the qualities of the resulting film. FIG. 7 shows that a layer 132 may also be used as described with regards to FIG. 2F. Any of the method suggested previously with regards to sodium content may also be adapted for use with the embodiments shown in FIGS. 5-7.

It should be understood that other embodiments of the present invention also disclose material comprised of at least two elements wherein the amount of at least one element in the material is less than about 50 molar percent of the total molar amount of that element in the precursor material. This includes embodiments where the amount of group IB element is less than the amount of group IIIA element in inter-metallic material. As a nonlimiting example, this may include other group IB poor, group IB-IIIA materials such as Cu-poor CuₓIn_{y} particles (where x<y). The amount of group IIIA material may be in any range as desired (more than about 50 molar percent of the element in the precursor material or less than 50 molar percent). In another nonlimiting example, Cu₁Ga₂ may be used with elemental Cu and elemental In. Although this material is not an inter-metallic material, this material is a intermediate solid solution and is different from a terminal solid solution. All solid particles are created based on a Cu₁Ga₂ precursor. In this embodiment, no emulsions are used.

In still other embodiments of the present invention, other viable precursor materials may be formed using a group IB rich, group IB-IIIA material. As a nonlimiting example, a variety of intermediate solid-solutions may be used. Cu—Ga (38 at % Ga) may be used in precursor layer 500 with elemental indium and elemental copper. In yet another embodiment, Cu—Ga (30 at % Ga) may be used in precursor layer 500 with elemental copper and elemental indium. Both of these embodiments describe Cu-rich materials with the Group IIIA element being less than about 50 molar percent of that element in the precursor material. In still further embodiments, Cu—Ga (multiphasic, 25 at % Ga) may be used with elemental copper and indium to form the desired precursor layer. It should be understood that nanoparticles of these materials may be created by mechanical milling or other size reduction methods. In other embodiments, these particles may be made by electroexplosive wire (EEW) processing, evaporation condensation (EC), pulsed plasma processing, or other methods. Although not limited to the following, the particles sizes may be in the range of about 10 nm to about 1 micron. They may be of any shape as described herein.

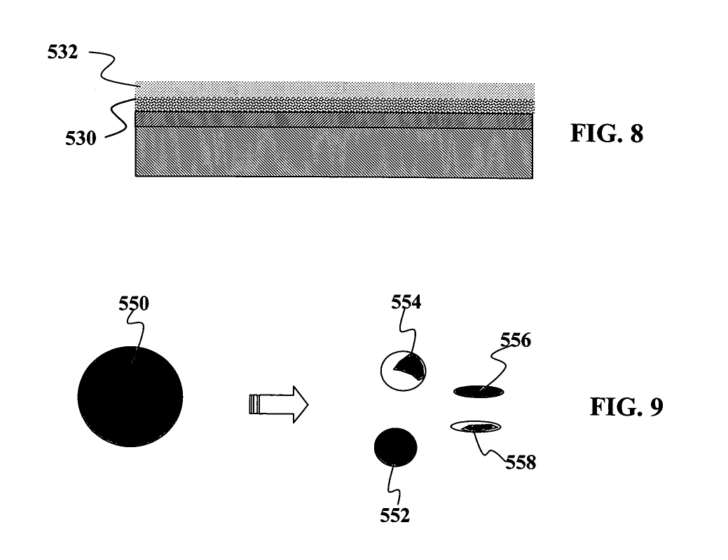

Referring now to FIG. 8, in a still further embodiment of the present invention, two or more layers of materials may be coated, printed, or otherwise formed to provide a precursor layer with the desired stoichiometric ratio. As a nonlimiting example, layer 530 may contain a precursor material having Cu₁₁In₉ and a Ga source such as elemental Ga and/or GaₓSe_{y}. A copper rich precursor layer 532 containing Cu₇₈In₂₈ (solid-solution) and elemental indium or InₓSe_{y} may be printed over layer 530. In such an embodiment, the resulting overall ratios may have Cu/(In+Ga)=0.85 and Ga/(In+Ga) 0.19. In one embodiment of the resulting film, the film may have a stoichiometric ratio of Cu/(In+Ga) with a compositional range of about 0.7 to about 1.0 and Ga/(In+Ga) with a compositional range of about 0.05 to about 0.3.

Referring now to FIG. 9, it should be understood that in some embodiments of the present invention, the inter-metallic material is used as a feedstock or starting material from which particles and/or nanoparticles may be formed. As a nonlimiting example, FIG. 9 shows one inter-metallic feedstock particle 550 being processed to form other particles. Any method used for size reduction and/or shape change may be suitable including but not limited to milling, EEW, EC, pulsed plasma processing, or combinations thereof. Particles 552, 554, 556, and 558 may be formed. These particles may be of varying shapes and some may contain only the inter-metallic phase while others may contain that phase and other material phases.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, still other embodiments of the present invention may use a Cu—In precursor material wherein Cu—In contribute less than about 50 percent of both Cu and In found in the precursor material. The remaining amount is incorporated by elemental form or by non IB-IIIA alloys. Thus, a Cu₁₁In₉ may be used with elemental Cu, In, and Ga to form a resulting film. In another embodiment, instead of elemental Cu, In, and Ga, other materials such as Cu—Se, In—Se, and/or Ga—Se may be substituted as source of the group IB or IIIA material. Optionally, in other embodiment, the IB source may be any particle that contains Cu without being alloyed with In and Ga (Cu, Cu—Se). The IIIA source may be any particle that contains In without Cu (In—Se, In—Ga—Se) or any particle that contains Ga without Cu (Ga, Ga—Se, or In—Ga—Se). Other embodiments may have these combinations of the IB material in a nitride or oxide form. Still other embodiments may have these combinations of the IIIA material in a nitride or oxide form. The present invention may use any combination of elements and/or selenides (binary, ternary, or multinary) may be used. Optionally, some other embodiments may use oxides such as In₂O₃ to add the desired amounts of materials. It should be understood for any of the above embodiments that more than one solid solution may be used, multi-phasic alloys, and/or more general alloys may also be used. For any of the above embodiments, the annealing process may also involve exposure of the compound film to a gas such as H₂, CO, N₂, Ar, H₂Se, or Se vapor.

It should also be understood that several intermediate solid solutions may also be suitable for use according to the present invention. As nonlimiting examples, a composition in the δ phase for Cu—In (about 42.52 to about 44.3 wt % In) and/or a composition between the δ phase for Cu—In and Cu₁₆In₉ may be suitable inter-metallic materials for use with the present invention to form a group IB-IIIA-VIA compound. It should be understood that these inter-metallic materials may be mixed with elemental or other materials such as Cu—Se, In—Se, and/or Ga—Se to provide sources of the group IB or IIIA material to reach the desired stoichiometric ratios in the final compound. Other nonlimiting examples of inter-metallic material include compositions of Cu—Ga containing the following phases: γ₁ (about 31.8 to about 39.8 wt % Ga), γ₂ (about 36.0 to about 39.9 wt % Ga), γ₃ (about 39.7 to about −44.9 wt % Ga), the phase between γ₂ and γ₃, the phase between the terminal solid solution and γ₁, and θ (about 66.7 to about 68.7 wt % Ga). For Cu—Ga, a suitable composition is also found in the range in between the terminal solid-solution of and the intermediate solid-solution next to it. Advantageously, some of these inter-metallic materials may be multi-phasic which are more likely to lead to brittle materials that can be mechanically milled. Phase diagrams for the following materials may be found in ASM Handbook, Volume 3 Alloy Phase Diagrams (1992) by ASM International and fully incorporated herein by reference for all purposes. Some specific examples (fully incorporated herein by reference) may be found on pages 2-168, 2-170, 2-176, 2-178, 2-208, 2-214, 2-257, and/or 2-259.

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. The following related applications are fully incorporated herein by reference for all purposes: U.S. patent application Ser. No. 11/081,163, entitled “METALLIC DISPERSION”, which was filed on Mar. 16, 2005, U.S. patent application Ser. No. 10/782,017, entitled “SOLUTION-BASED FABRICATION OF PHOTOVOLTAIC CELL” which was filed Feb., 19, 2004 and published as US Patent Application Publication 20050183767, U.S. patent application Ser. No. 10/943,658 entitled “FORMATION OF CIGS ABSORBER LAYER MATERIALS USING ATOMIC LAYER DEPOSITION AND HIGH THROUGHPUT SURFACE TREATMENT” which was filed Sep. 18, 2004 and published as US Patent Application Publication 20050186342, U.S. patent application Ser. No. 11/243,492 entitled “FORMATION OF COMPOUND FILM FOR PHOTOVOLTAIC DEVICE” which was filed Oct. 3, 2005, and U.S. patent application Ser. No. 11/243,492, entitled “FORMATION OF COMPOUND FILM FOR PHOTOVOLTAIC DEVICE” filed Oct. 3, 2005, the entire disclosures of the foregoing are incorporated herein by reference. Copending U.S. patent application Ser. No.______ (Attorney Docket No. NSL-068) filed Mar. 30, 2006 is also fully incorporated herein by reference for all purposes.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A method comprising:
forming a precursor layer on a substrate, wherein the precursor layer comprises one or more discrete layers comprising:
a) at least a first layer containing one or more group IB elements and two or more different group IIIA elements;
b) at least a second layer containing elemental chalcogen particles; and
heating the precursor layer to a temperature sufficient to melt the chalcogen particles and to react the chalcogen particles with the one or more group IB elements and group IIIA elements in the precursor layer to form a film of a group IB-IIIA-chalcogenide compound;
wherein at least one set of the particles in the precursor layer are inter-metallic particles containing at least one group IB-IIIA inter-metallic alloy phase.

2. The method of claim 1 wherein the first layer is formed over the second layer.

3. The method of claim 1 wherein the second layer is formed over the first layer.

4. The method of claim 1 wherein the first layer also contains elemental chalcogen particles.

5. The method of claim 1 wherein the first layer group IB elements in the form of a group IB-chalcogenide.

6. The method of claim 1 wherein the first layer group IIIA elements in the form of a group IIIA-chalcogenide.

7. The method of claim 1 further comprising a third layer containing elemental chalcogen particles.

8. The method of claim 1 wherein the two or more different group IIIA elements include indium and gallium.

9. The method of claim 1 wherein the group IB element is copper.

10. The method of claim 1, wherein chalcogen particles are particles of selenium, sulfur or tellurium.

11. The method of claim 1 wherein the precursor layer is substantially oxygen-free.

12. The method of claim 1 wherein forming the precursor layer includes forming a dispersion including nanoparticles containing one or more group IB elements and nanoparticles containing two or more group IIIA elements, spreading a film of the dispersion onto the substrate.

13. The method of claim 1 wherein forming the precursor layer includes sintering the film to form the precursor layer.

14. The method of claim 1 herein sintering the precursor layer takes place before the step of disposing the layer containing elemental chalcogen particles over the precursor layer.

15. The method of claim 1 wherein the substrate is a flexible substrate and wherein forming the precursor layer and/or disposing the layer containing elemental chalcogen particles over the precursor layer, and/or heating the precursor layer and chalcogen particles includes the use of roll-to-roll manufacturing on the flexible substrate.

16. The method of claim 1 wherein the substrate is an aluminum foil substrate.

17. The method of claim 1 wherein the group IB-IIIA-chalcogenide compound is of the form Cu_{z}In₍₁₋ₓ₎GaₓS_{2(1-y)}Se_{2y}, where 0.5≦z≦1.5, 0≦x≦1.0 and 0≦y≦1.0.

18. The method of claim 1, wherein heating of precursor layer and chalcogen particles includes heating the substrate and precursor layer from an ambient temperature to a plateau temperature range of between about 200° C. and about 600° C., maintaining a temperature of the substrate and precursor layer in the plateau range for a period of time ranging between about a fraction of a second to about 60 minutes, and subsequently reducing the temperature of the substrate and precursor layer.

19. The method of claim 1 wherein the film includes a group IB-IIIA-VIA compound.

20. The method of claim 1 wherein reacting comprises heating the layer in the suitable atmosphere.

21. The process of claim 1 wherein at least one set of the particles in the dispersion is in the form of nanoglobules.

22. The method of claim 1 wherein at least one set of the particles in the dispersion are in the form of nanoglobules and contain at least one group IIIA element.

23. The method of claim 1 wherein at least one set of the particles in the dispersion is in the form of nanoglobules comprising of a group IIIA element in elemental form.

24. The method of claim 1 wherein the inter-metallic phase is not a terminal solid solution phase.

25. The method of claim 1 wherein the inter-metallic phase is not a solid solution phase.

26. The method of claim 1 wherein inter-metallic particles contribute less than about 50 molar percent of group IB elements found in all of the particles.

27. The method of claim 1 wherein inter-metallic particles contribute less than about 50 molar percent of group IIIA elements found in all of the particles.

28. The process of claim 1 wherein inter-metallic particles contribute less than about 50 molar percent of the group IB elements and less than about 50 molar percent of the group IIIA elements in the dispersion deposited on the substrate.

29. The method of claim 1 wherein inter-metallic particles contribute less than about 50 molar percent of the group IB elements and more than about 50 molar percent of the group IIIA elements in the dispersion deposited on the substrate.

30. The process of claim 1 wherein inter-metallic particles contribute more than about 50 molar percent of the group IB elements and less than about 50 molar percent of the group IIIA elements in the dispersion deposited on the substrate.

31. The process of claim 10 wherein the molar percent is based on a total molar mass of the elements in all particles present in the dispersion.

32. The process of claim 1 wherein at least some of the particles have a platelet shape.

33. The process of claim 1 wherein a majority of the particles have a platelet shape.

34. The process of claim 1 wherein all of the particles have a platelet shape.

35. The method of claim 1 wherein the depositing step comprises coating the substrate with the dispersion.

36. The process of claim 1 wherein the dispersion comprises an emulsion.

37. The method of claim 1 wherein the inter-metallic material is a binary material.

38. The method of claim 1 wherein the inter-metallic material is a ternary material.

39. The process of claim 1 wherein the inter-metallic material comprises Cu₁In₂.

40. The method of claim 1 wherein the inter-metallic material comprises a composition in a δ phase of Cu₁In₂.

41. The method of claim 1 wherein the inter-metallic material comprises a composition in between a δ phase of Cu₁In₂ and a phase defined by Cu₁₆In₉.

42. The method of claim 1 wherein the inter-metallic material comprises Cu₁Ga₂.

43. The method of claim 1 wherein the inter-metallic material comprises an intermediate solid-solution of Cu₁Ga₂.

44. The method of claim 1 wherein the inter-metallic material comprises Cu₆₈Ga₃₈.

45. The method of claim 1 wherein the inter-metallic material comprises Cu₇₀Ga₃₀.

46. The method of claim 1 wherein the inter-metallic material comprises Cu₇₅Ga₂₅.

47. The method of claim 1 wherein the inter-metallic material comprises a composition of Cu—Ga of a phase in between the terminal solid-solution and an intermediate solid-solution next to it.

48. The method of claim 1 wherein the inter-metallic comprises a composition of Cu—Ga in a γ₁ phase (about 31.8 to about 39.8 wt % Ga).

49. The method of claim 1 wherein the inter-metallic comprises a composition of Cu—Ga in a γ₂ phase (about 36.0 to about 39.9 wt % Ga).

50. The method of claim 1 wherein the inter-metallic comprises a composition of Cu—Ga in a γ₃ phase (about 39.7 to about −44.9 wt % Ga).

51. The method of claim 1 wherein the inter-metallic comprises a composition of Cu—Ga in a θ phase (about 66.7 to about 68.7 wt % Ga).

52. The method of claim 1 wherein the inter-metallic comprises a composition of Cu—Ga in a phase between γ₂ and γ₃.

53. The method of claim 1 wherein the inter-metallic comprises a composition of Cu—Ga in a phase between the terminal solid solution and γ₁.

54. The method of claim 1 wherein the inter-metallic material comprises Cu-rich Cu—Ga.

55. The method of claim 1 wherein gallium is incorporated as a group IIIA element in the form of a suspension of nanoglobules.

56. The process of claim 55 wherein nanoglobules of gallium are formed by creating an emulsion of liquid gallium in a solution.

57. The process of claim 55 wherein gallium is quenched below room temperature.

58. The process of claim 55 further comprising maintaining or enhancing a dispersion of liquid gallium in solution by stirring, mechanical means, electromagnetic means, ultrasonic means, and/or the addition of dispersants and/or emulsifiers.

59. The method of claim 1 further comprising adding a mixture of one or more elemental particles selected from: aluminum, tellurium, or sulfur.

60. The method of claim 1 wherein the suitable atmosphere contains at least one of the following: selenium, sulfur, tellurium, H₂, CO, H₂Se, H₂S, Ar, N₂ or combinations or mixture thereof.

61. The method of claim 1 wherein the suitable atmosphere contains at least one of the following: H₂, CO, Ar, and N₂.

62. The method of claim 1 wherein one or more classes of the particles are doped with one or more inorganic materials.

63. The method of claim 1, wherein one or more classes of the particles are doped with one or more inorganic materials chosen from the group of aluminum (Al), sulfur (S), sodium (Na), potassium (K), or lithium (Li).

64. The process of claim 1 wherein the particles are nanoparticles.

65. The process of claim 1 further comprising forming the particles from a feedstock having an inter-metallic phase.

66. The method of claim 1 further comprising forming the particles from a feedstock having an inter-metallic phase and nanoparticles are formed by one of the following processes: milling, electroexplosive wire (EEW) processing, evaporation condensation (EC), pulsed plasma processing, or combinations thereof.

67. A method for forming a film of a group IB-IIIA-chalcogenide compound, the method comprising:
forming a precursor layer on a substrate, the precursor layer containing one or more group IB elements and one or more group IIIA elements;
sintering the precursor layer;
after sintering the precursor layer, forming a layer containing elemental chalcogen particles over the precursor layer; and
heating the precursor layer and chalcogen particles to a temperature sufficient to melt the chalcogen particles and to react the chalcogen particles with the group IB element and group IIIA elements in the precursor layer to form a film of a group IB-IIIA-chalcogenide compound;
wherein at least one set of the particles in the precursor layer are inter-metallic particles containing at least one group IB-IIIA inter-metallic alloy phase.

68. The method of claim 67 wherein the substrate is an aluminum foil substrate.

69. A method comprising:
forming a precursor layer containing particles having one or more group IB elements and two or more different group IIIA elements;
forming a layer containing surplus chalcogen particles providing a source of excess chalcogen, wherein the precursor layer and the surplus chalcogen layer are adjacent to one another; and
heating the precursor layer and the surplus chalcogen layer to a temperature sufficient to melt the particles providing the source of excess chalcogen and to react the particles with the one or more group IB elements and group IIIA elements in the precursor layer to form a film of a group IB-IIIA-chalcogenide compound on a substrate;
wherein at least one set of the particles in the precursor layer are inter-metallic particles containing at least one group IB-IIIA inter-metallic alloy phase.
